(19) United States
(12) Patent Application Publication
(10) Pub. No.: US 2005/0260855 A1
(43) Pub. Date: Nov. 24, 2005

(54) Method and apparatus for planarizing a semiconductor wafer

(75) Inventor: David K. Watts, Oakland, CA (US)

Correspondence Address: TOLER & LARSON & ABEL L.L.P., 5000 PLAZA ON THE LAKE STE 265, AUSTIN, TX, 78746, US

(73) Assignee: ACUTE, INC., Oakland, CA (US)

(21) Appl. No.: 11/114,907

(22) Filed: Apr. 26, 2005

Related U.S. Application Data
(63) Continuation of application No. PCT/US03/33790, filed on Oct. 27, 2003.
(60) Provisional application No. 60/421,668, filed on Oct. 28, 2002.

(51) Int. Cl. H01L 21/8242; H01L 21/4763; H01L 21/302

(52) U.S. Cl. 438/690; 438/692; 438/693; 438/633; 438/626

(57) ABSTRACT

A method for planarizing a semiconductor wafer includes providing a fluid on a surface of the wafer, the fluid containing particles, and generating a field to apply a force to the particles, the force having a component that is normal to the surface such that the particles contact the surface to remove material therefrom. Alternative methods, semiconductor devices and semiconductor processing apparatuses are also disclosed.

### BACKGROUND

1. Disclosure of the Invention

The present invention relates generally to semiconductor wafer processing, and more particularly, to a method and apparatus for polishing or planarization and deposition of materials on semiconductor devices, as well as semiconductor devices made thereby.

2. Description of the Related Art

As part of the semiconductor device fabrication process, materials such as copper, tungsten, aluminum, silicon, silicon dioxide, silicon nitride, and others are normally deposited on the surface of a semiconductor wafer, and a chemical mechanical polishing (‘CMP’) process is used to remove material from the semiconductor wafer to planarize the surface. Prior art FIG. 1 is a perspective view of a CMP system 5 used to perform a conventional CMP process and FIG. 2 is an exploded cross-sectional view 9 of a portion of the CMP system 5. In FIG. 1 the CMP system 5 includes a rotating carrier 16, above a polishing pad 10, placed on a rotating table 12. FIG. 2 shows the rotating carrier 16 containing a semiconductor wafer 14, and the front surface 17 of the semiconductor wafer 14 is pressed and rubbed against the polishing pad 10 to remove material from the semiconductor wafer surface. Typically, the CMP process will reduce the topography of the surface such that the surface is polished or planarized.

During a conventional CMP process, a chemical liquid 18 is also required and is delivered to the CMP system 5 by a first delivery device 7. Although not shown, typically a fine particle abrasive such as alumina or silica, normally already mixed into the chemical liquid 18 and known conventionally as slurry, is also required for the CMP process. The dimensions of the abrasive particles typically range from a few nanometers to a few micrometers. The abrasive particles need not be already mixed in the chemical liquid 18, but rather may be embedded in the polishing pad 10. Alternatively, the abrasive particles may also be separately delivered to the CMP system 5 by a second delivery device (not shown) and mixed with the chemical liquid 18 on the polishing pad 10. In operation, the chemical liquid 18 and/or slurry containing abrasive particles is used to continuously wet the polishing pad 10 while the pad 10 is mechanically rubbed against the front surface 17 of the semiconductor wafer 14, which generally includes contacting and forcing the particles of the slurry against the wafer, enabling removal and planarization of material on the surface of the wafer 14.

Recently, CMP has received a tremendous and growing amount of investigation and engineering as an enabling technology for manufacturing high-speed semiconductor devices. This is because, to enable performance, new materials are being used in semiconductor device fabrication. High-conductivity copper (replacing aluminum) has been integrated into semiconductor devices. The copper typically forms lines and plugs (also vias, contacts), which connect multiple semiconductor devices on a semiconductor wafer. Low dielectric constant materials (replacing silicon dioxide) are also being evaluated for use as the material between the interconnect lines. Further, along with the introduction of copper lines, known ‘Damascene’ (also inlaid, dual Damascene, or dual inlaid) processing has been used to form the copper lines and/or vias. During the Damascene process, a layer of copper is typically deposited over a patterned dielectric material and the surface of the wafer is planarized with a CMP process such that copper is removed from portions of the surface to expose the underlying dielectric material. The copper remains embedded in patterned areas to form lines and/or vias, The CMP process may then be followed by deposition of another layer over the surface.

Further, to improve the performance of semiconductor devices, more and more layers are required on a single semiconductor device. Since each such layer is generally planarized prior to adding subsequent layers, the CMP process is used more frequently. In addition, semiconductor devices are shrinking to improve performance, so the device features such as the lines are getting smaller as more features are being formed in a more compact area. The increasing number of layers and the shrinking features means that the requirements of processes such as deposition and CMP are becoming increasingly more challenging and more important to the overall semiconductor manufacturing process.

Despite the relatively successful implementation of CMP processing in state of the art fabrication process flows, numerous issues exist, particularly in light of the evolution of semiconductor processing, which utilizes increasingly sophisticated layered structures and incorporates new materials. Particular areas of concern include damage to the layers deposited on a substrate (e.g., dielectric materials, metal lines), surface contamination, adequacy of planarization/polishing, processing costs, and throughput.

In an attempt to address the needs of the industry with new generation planarization technologies, new approaches have been proposed such as electroetching or electropolishing. These approaches attempt to planarize with minimal pressures or shear forces compared to the CMP process, thereby minimizing defects and damage to the wafer surface. Such chemical or electrochemical approaches may have difficulty in planarizing wide lines (for example, copper lines wider than about 50 micrometers).

Other polishing techniques focus on manipulation of the rheological properties of the slurry used for polishing, by using slurries that have flow properties that change in relation to an applied electromagnetic field. However, while use of such rheological controllable fluids represents an interesting approach, it has not been generally implemented in semiconductor device processing and remains unsuitable for polishing or planarizing state of the art devices, which utilize a combination of low k dielectrics and copper lines. In part, such processes suffer from suitable process control to prevent damage while ensuring adequate planarization.

A need therefore still exists for improved CMP processing, CMP apparatuses, and semiconductor devices having advantageous features enabled by next-generation CMP processing.

### SUMMARY

According to one aspect, a method for planarizing a semiconductor wafer includes providing a fluid on a surface of the wafer, the fluid containing particles, and generating a field to apply a force to the particles, the force having a component that is normal to the surface such that the particles contact the surface to remove material therefrom.

According to another aspect, an apparatus for planarizing a semiconductor wafer includes a wafer holder for receiving the semiconductor wafer having a surface, a fluid inlet to provide a fluid on the surface of the semiconductor wafer, and a field generator for forcing the particles in the fluid to impact the surface of the semiconductor wafer and remove material therefrom.

According to another aspect, a method of forming a semiconductor device includes depositing a dielectric layer on a semiconductor wafer, depositing a conductive layer on the semiconductor wafer such that the conductive layer overlies the dielectric layer and defines an upper surface, providing a fluid on the upper surface of the semiconductor wafer, the fluid containing particles, and generating a field to force the particles in the fluid to impact the upper surface of the semiconductor wafer and remove material therefrom.

According to another aspect, a method for polishing a semiconductor wafer includes providing a semiconductor wafer comprising a dielectric material and a conductive layer overlying the dielectric material, said semiconductor wafer having a plurality of semiconductor die regions, and said dielectric material having a dielectric constant of less than about 2.5, polishing a surface of the semiconductor wafer to remove a portion of the conductive layer and expose a portion of the dielectric material, leaving behind conductive material forming lines of width not greater than about 1 micrometer and lines of width greater than about 50 micrometers, and spaced apart from each other by portions of the dielectric material, wherein a plurality of lines exist that have widths not greater than 1 micrometer and that are spaced apart from each other by dielectric material of width less than 1 micrometer, and wherein damage to the lines of conductive material and to the dielectric material is minimized to provide a yield of at least about 30%.

According to another aspect, a semiconductor device includes a substrate, an active device formed on the substrate, a dielectric layer overlying the active device, the dielectric layer having a trench that has a trench height, and a metal feature comprising copper, provided in the trench, wherein a height ratio hₗₖ/(hₗₖ+hₕₖ) is not less than about 0.7, hₗₖ is a height of a low dielectric constant portion of the dielectric layer that extends along the height of the trench, and hₕₖ is a height of a high dielectric constant portion of the dielectric layer that extends along the height of the trench, wherein the low dielectric constant portion has a dielectric constant k not greater than about 2.7.

According to another aspect, a semiconductor device includes a substrate, an active device formed on the substrate, a low k dielectric layer overlying the active device, the low k dielectric layer having a dielectric constant k not greater than about 2.7 and having a surface, and a metal feature comprising copper having an upper surface, extending through the dielectric layer. The upper surface of the metal feature is substantially coplanar with the surface of the low k dielectric layer, quantified by a step height not greater than 1000 Å.

### BRIEF DESCRIPTION OF THE DRAWINGS

The present invention may be better understood, and its numerous objects, features, and advantages made apparent to those skilled in the art by referencing the accompanying drawings.

FIG. 1 is a prior art CMP apparatus.

FIG. 2 illustrates an exploded view of a prior art polishing assembly, which utilized a polishing pad to execute planarization.

FIG. 3 illustrates a planarization apparatus that may be used according to embodiments herein.

FIGS. 4-10 illustrate a process flow for semiconductor device fabrication according to an embodiment of the present invention.

FIGS. 11-14 illustrate another semiconductor process flow.

FIG. 15 illustrates a prior art approach that utilizes a magnetic field and a polishing pad to execute polishing.

FIG. 16 illustrates a planarization approach that may be used according to embodiments herein.

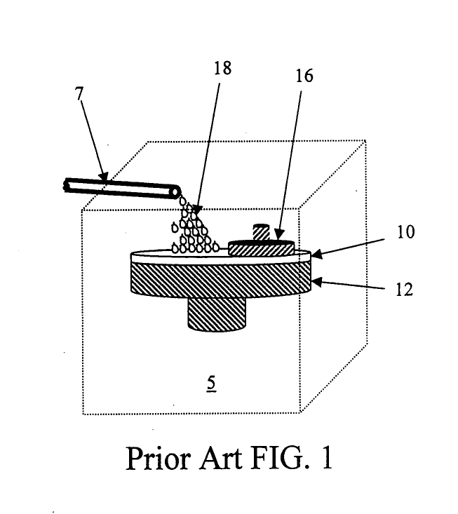

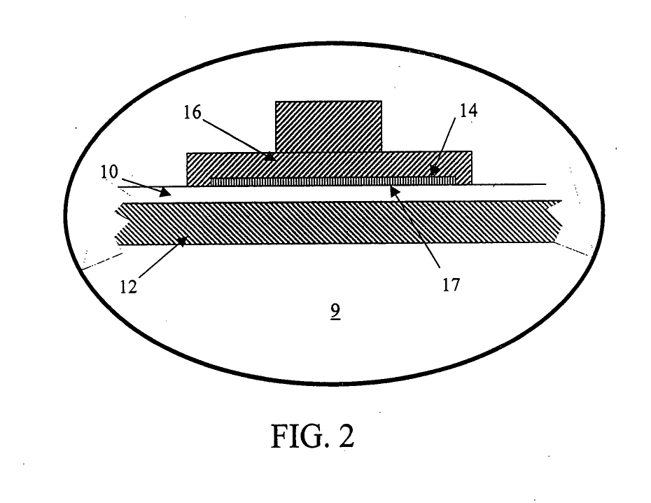

The use of the same reference symbols in different drawings indicates similar or identical items.

### DESCRIPTION OF THE PREFERRED EMBODIMENT(S)

One aspect of the present invention provides for a method of planarizing a semiconductor wafer. The planarization method is performed by providing a fluid on the surface of the wafer, the fluid containing particles. The fluid may be flowed across the surface. Further, a field is generated to apply a force to individual particles, and bias the particles so as to translate to the surface of the semiconductor wafer at which planarization is carried out. In particular, by biasing and translating the particles, the particles contact the surface and remove material therefrom due to the force of the biased particles on the material forming the exposed surface.

The fluid in an embodiment of this invention may be a liquid such as water, and the particles may be made up of ceramic material such as silica, alumina, or silicon carbide; metals such as gold, silver or platinum; metal oxides such as copper oxide; elements such as diamond; or organic material such as organic polymers. The foregoing materials may be particularly useful for embodiments that utilize an electric field to bias and translate the particles contained in the fluid medium. In the case of the use of a magnetic field, typically a ferromagnetic material containing elements such as iron, manganese, zinc, nickel, cobalt, and combinations thereof is utilized. In embodiments taking advantage of a mechanical energy field such as pressure waves or sonic waves traveling through the liquid medium, typically any inert abrasive material may be utilized. Generally, the selection of the inert material is chosen to be compatible with the materials of the semiconductor active devices. The particle dimensions may range between about 10 nanometers and about 800 micrometers, such as an average particle diameter within a range of about 0.1 μm to about 500 μm. In addition, one or more chemicals may be added to the fluid. For example a complexing agent such as carboxylates, alcohols, amines, phosphonates, amides, sulfonates, thiols, sulfides, or azo compounds might be added. The added chemical may also be an oxidizing agent such as peroxides, chlorates, iodates, persulfates, perchlorates, periodates, or metal ions. Further, the fluid may be recycled and reused.

The force on the particles may be applied by a field that may be generated by any means that can be used to bias the particles and can cause translation of the particles to the surface without direct physical contact to the particles. Although a polishing pad may be used in combination with techniques disclosed herein, such as use of a pad with generation of a field, according to a particular development the pad may be eliminated. That is, the force used to bias the particles to effect planarization and/or polishing may be achieved without use of a polishing pad. The field may be a magnetic field, an electric field, or an mechanical energy field such as a sonic field, which propagates through the fluid medium.

In embodiments that utilize a pad, it may be implemented in the process in various ways. For example, the pad may be used to effect planarization in a manner similar to the state of the art, but supplemented with a field to effect particle-specific force on the particles. In this regard, the pressure on the pad may be lowered to, among other things, prevent damage to the materials on the substrate such as delicate low k dielectrics. Alternatively, or additionally, after a certain depth of polishing, pressure on the pad may be alleviated partially or entirely, thereby further emphasizing polishing by field effects rather than the global force by use of the pad.

The state of removal of material may be monitored during planarization of the wafer. For example, the state of removal may be monitored by probing the surface of the wafer with electromagnetic radiation, and analyzing the data of reflected electromagnetic radiation, or by detecting an electric current, an electric potential, an electric charge, a magnetic field, or a chemical. The data obtained from monitoring the state of removal may allow for the process parameters such as the field strength, the fluid flow rate, and/or the chemical additives to be changed based on the state of removal. For example, during planarization of a layer such as copper, the monitoring may indicate that an underlying material such as silicon dioxide or tantalum nitride becomes exposed, or that the material being removed reaches a particular thickness. Based on the state of removal, the flow of a first fluid containing particles may be stopped, and a second fluid may be flowed over the wafer. For example, the first fluid may contain components designed to remove and polish copper, whereas the second fluid may contain components designed to remove tantalum nitride. Alternatively, the second fluid might not contain particles and the field may be changed during the flowing of the second fluid so that particles are repelled from the surface so as to clean the wafer surface. The data obtained from monitoring the state of removal may also be used to change the process parameters in between each wafer processed.

Another embodiment calls for depositing a material, before, after, and/or during the planarizing. The depositing and removal may be performed in a single chamber. The deposition may be achieved by electroplating or electroless plating, and the deposited material may be an element, or an alloy of elements selected from the group consisting of copper, silver, ruthenium, platinum, palladium, cobalt, nickel, tin, tungsten, phosphorus, boron, tantalum, titanium and nitrogen.

A layer of a conductive material such as copper may be deposited, in one embodiment, over a dielectric material such as silicon dioxide, or over a material that has a low dielectric constant relative to that of silicon dioxide. For example, the dielectric material may have a dielectric constant less than about 3.0, such as less than about 2.7, 2.6, 2.5, 2.4, 2.3, or even 2.2. The fluid containing particles biased in a field may be used to remove the conductive material and expose portions of the dielectric material that were covered by the conductive material.

The materials with low dielectric constants are typically softer and more susceptible to deformation compared to silicon dioxide, for example such as polymers, such as organic polymers. For example such materials may have hardness values that are less than about 60%, such as less than about 50, 40, or even 30%, of the value for typical silicon dioxide films. The low k materials may also have a lower Young's modulus of elasticity value compared to silicon dioxide. Such low k materials may have Young's modulus values of less than about 30 GPa, such as less than about 20, 10 or even 5 GPa. Further, the material may have porosity, such as not less than 15, 20, or even 25%, further reducing the dielectic constant. The dielectric material may be patterned with an opening by a process such as etching so that the deposited conductive material fills the opening. After planarization, conductive material may remain in the opening to form a via and/or a line. A plurality of active devices, vias and lines may be formed on a single wafer, and the wafer may be diced into a plurality of semiconductor devices.

In one embodiment, after polishing a surface, conductive material is removed to expose underlying dielectric material. The conductive material may remain embedded in the dielectric material to form lines with a minimum dimension (typically line width) of less than about one micrometer and other lines with a minimum dimension of greater than about 50 micrometers. The polished surface may comprises a minimum of about 10% of the exposed dielectric material with the balance of the surface being remaining conductive material. In this embodiment, the polishing leaves a relative height difference of less than about 100 nanometers, preferably not greater than about 50, nanometers between a first location on the surface of the conductive material of a conductive feature (e.g., metal line or plug) at the lowest point of the feature, and a second location within a distance of 50 microns on the surface of the dielectric material from the first location, and leaves the polished surface with no scratches that have a depth greater than about 20 nanometers. In this regard, generally, the foregoing maximum step height is found on a majority of features, and particularly associated with features having a width (smallest dimension at the exposed surface, as opposed to length) of not less than 50 μm. This is particularly significant, as step height for such large features is typically difficult to control. A plurality of lines generally exist that have widths less than 1 micrometer and that are spaced apart from each other by dielectric material of width less than 1 micrometer. According to one feature, damage to the lines of conductive material and to the dielectric material is minimized to provide a yield of at least about 30%. The yield may be defined as a percentage portion of the semiconductor die regions that have the lines with a maximum step height as described above, and that have the lines free of electrical short circuits and free of electrical open circuits.

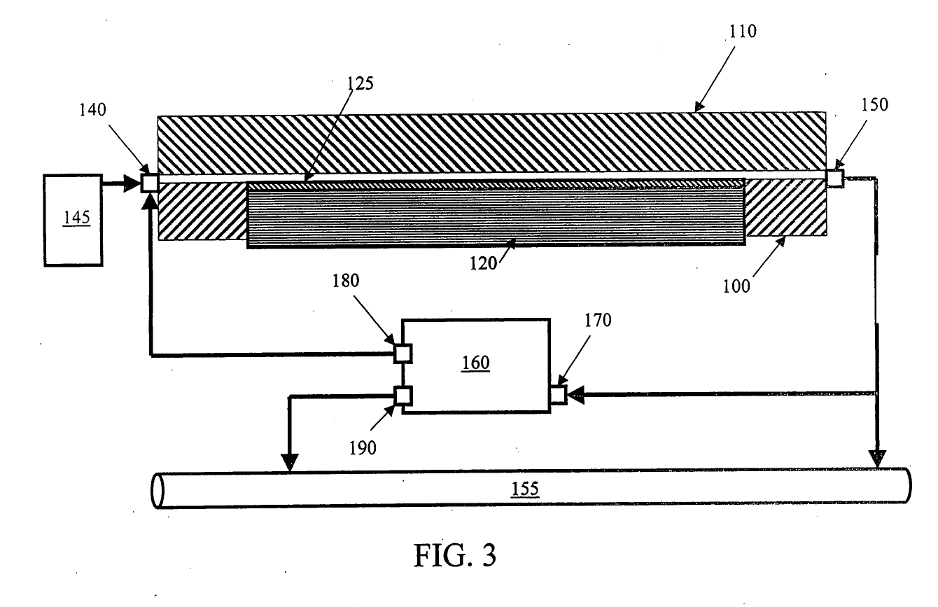

FIG. 3 represents a cross-sectional view of an embodiment of a planarization apparatus. In FIG. 3, a process chamber having a wafer holder 100 and an upper lid 110 contains a wafer 125 and an electromagnet 120. Although not shown, an electrical connection can be made to the electromagnet 120 to enable generating a magnetic field. The process chamber in FIG. 3 also includes an inlet nozzle 140 so that fluid from a source 145 is flowed into the chamber and across the surface of the wafer 125. Particles are generally present in the fluid or on the surface of the wafer 125, and the field may be set such that particles are forced and translated to the surface of the wafer 125. The process chamber in FIG. 3 also includes an outlet nozzle 150 to allow the fluid to exit from the chamber. The exiting fluid may either be sent to a drain 155, or sent to a treatment chamber 160. The treatment chamber 160 includes an entry port 170, a first exit port 180, and a second exit port 190. Fluid from the first exit port 180 of the treatment chamber 160 may be directed to the inlet nozzle 140 and re-flowed into the process chamber and across the surface of the wafer 125. Fluid from the second exit port 190 may be directed to the drain 155.

Typically, the wafer 125 is rotated such as about its central axis, during planarization. Alternatively or additionally, the wafer also is rotated in an orbiting fashion about a rotation axis which may be the geometric center of a wafer holder that may contain multiple wafers (not shown). According to a particular development, as discussed above, not only can planarization take place in the apparatus, but also deposition may take place. In this regard, planarization and deposition can take place in the same process chamber, which is beneficial for reducing the footprint of the apparatus in a semiconductor fabrication environment.

Although not shown in FIG. 3, the apparatus may also include a surface probe for monitoring the state of removal at the wafer surface during processing. The probe may project electromagnetic radiation onto the surface of the wafer, and monitor the data of electromagnetic radiation reflected from the wafer surface. In another embodiment the surface probe may monitor the change in an electric current, an electric potential, an electric charge, a magnetic field, or a chemical species.

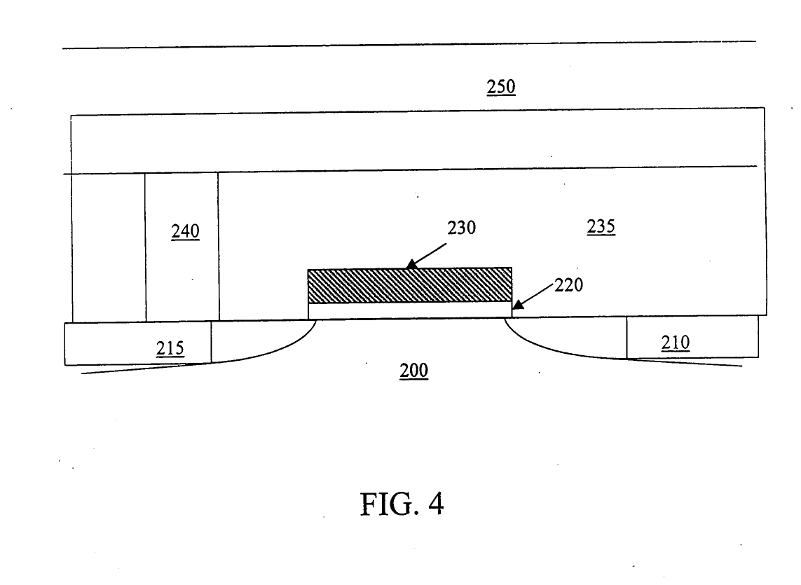

FIG. 4 represents a cross-sectional view of a semiconductor device with a deposited layer of material with low dielectric constant 250. In FIG. 4, the semiconductor device is formed from a substrate 200 that may be made of any conventional semiconductor material such as monocrystalline silicon, germanium, silicon on insulator or other types of semiconductor wafer material. A source region 215 and a drain region 210 have been formed in the substrate 200 using conventional semiconductor techniques after formation of the gate dielectric 220 and gate 230. As is well known in the industry, gate dielectrics 220 are typically formed of insulating type of material such as silicon dioxide while the gate 230 is a conducting material such as tungsten or polysilicon. The drain 210 and source 215 regions likewise are made of conventional semiconductor material that is doped with n-type or p-type dopants. Following formation of the gate 230, an interlevel dielectric (ILD) layer 235 is formed. The ILD layer 235 may be made of any conventional dielectric material such as silicon dioxide or materials with low dielectric constant such as polymers. The ILD layer 235 is etched to form an opening called a via, filled with a conductive material such as copper, tungsten or aluminum, and planarized to form a contact 240 (also plug, via). In FIG. 4, the contact 240 provides ohmic contact to the source region 215. Although it is not shown, the contact 240 may also be lined with a diffusion barrier material such as titanium nitride or tantalum nitride between the ILD material 235 and the conductive material 280. Although it is not shown in the cross sectional plane of FIG. 4, a similar contact plug, as contact plug 240, may be formed for the drain region 210. The layer of material with low dielectric constant 250 is then deposited over the device.

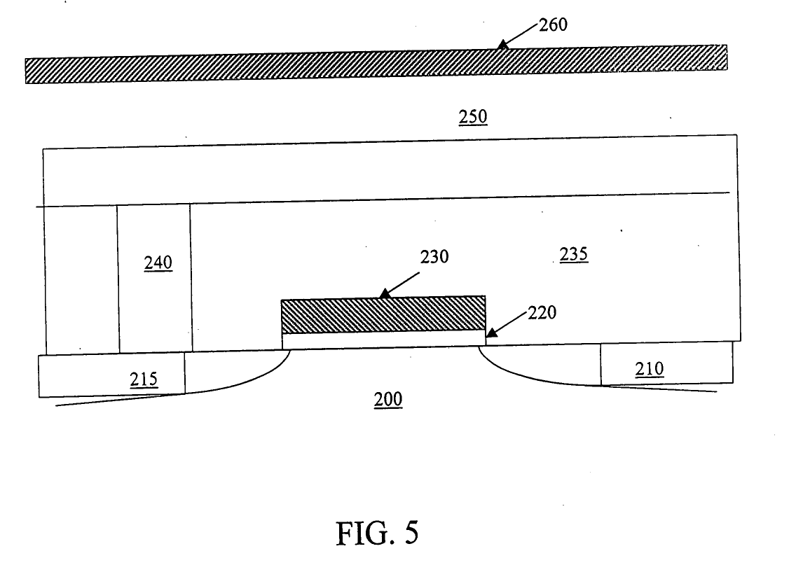

In FIG. 5, a pre-capping layer 260 is deposited over the material with low dielectric constant 250. The pre-capping layer is typically harder than the material with low dielectric constant 250 and may be made of any material such as silicon nitride, silicon carbide, silicon dioxide, or other types of material that may be deposited by processes known in the industry.

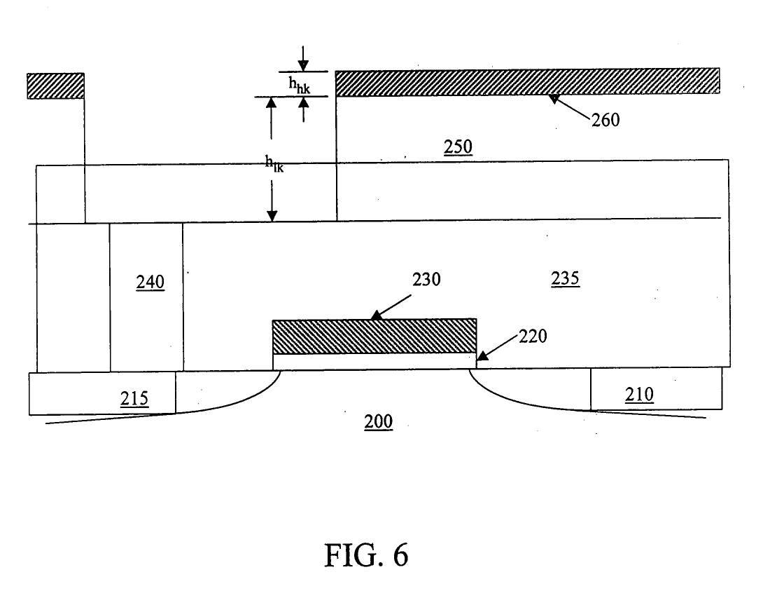

In FIG. 6, an etching process is used to create an opening or trench through the pre-capping layer 260 and the material with low dielectric constant 250. As shown, the structure has a particular height ratio of hₗₖ/(hₗₖ+hₕₖ). As shown, hₗₖ is the height of the low dielectric constant portion of the dielectric layer that extends along the height of the trench, while hₕₖ is the height of the pre-capping layer 260 or high dielectric constant portion of the dielectric layer that extends along the height of the trench made in the dielectric layer composed of low dielectric constant material 250 and pre-capping layer 260. Preferably, the height ratio is higher than 0.7, such as not less than about 0.8, 0.9, 0.95, or even 0.99. In one embodiment, the height ratio is about 1.0, such that the high dielectric portion is substantially eliminated in favor of substantially the entirety of the dielectric layer being formed of the low dielectric constant material. While a single trench is illustrated in FIG. 6, typically multiple trenches are disposed throughout the wafer at various locations, and a majority portion of such trenches meet the foregoing height ratio.

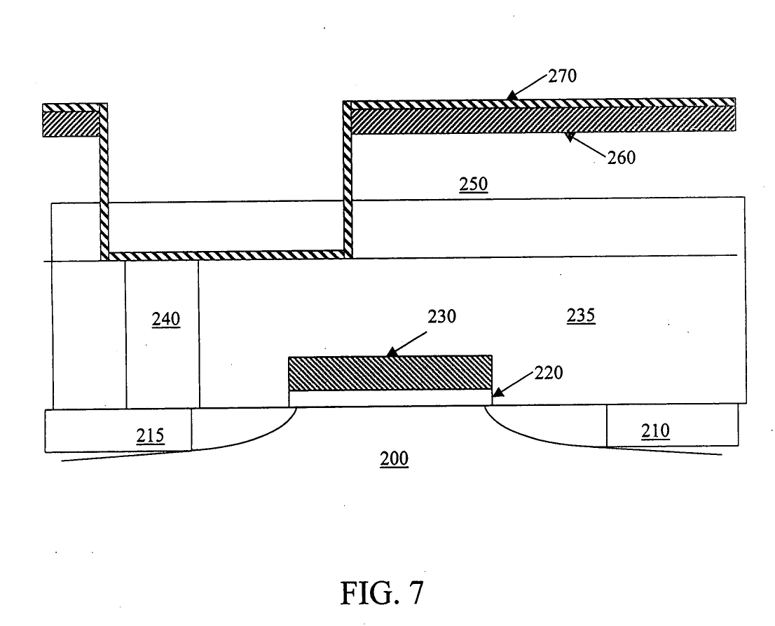

FIG. 7 shows a barrier layer 270 that has been deposited to cover the surface of the pre-capping layer 260, and the exposed surface of the material with low dielectric constant 250 in the trench. The barrier layer 270 may be formed of materials such as tantalum nitride, tantalum, titanium nitride, titanium, or other materials that may be deposited by processes known in the industry.

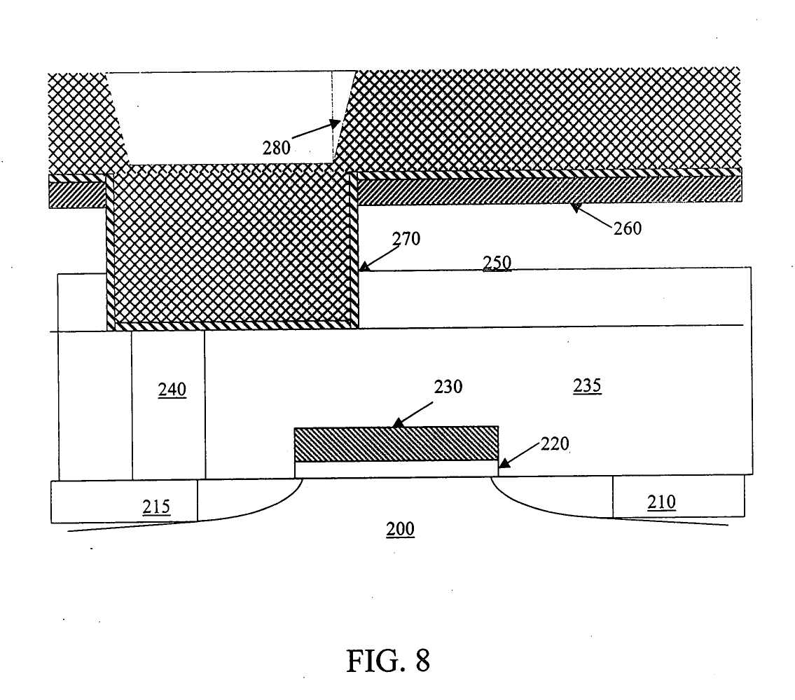

FIG. 8 shows a deposited layer of conductive material 280 over the barrier layer 270. The conductive material 280 is deposited to completely fill the trench. The conductive material 280 may be metals such as copper, aluminum, tungsten, silver, gold, or other conductive materials that may be deposited by processes known in the industry.

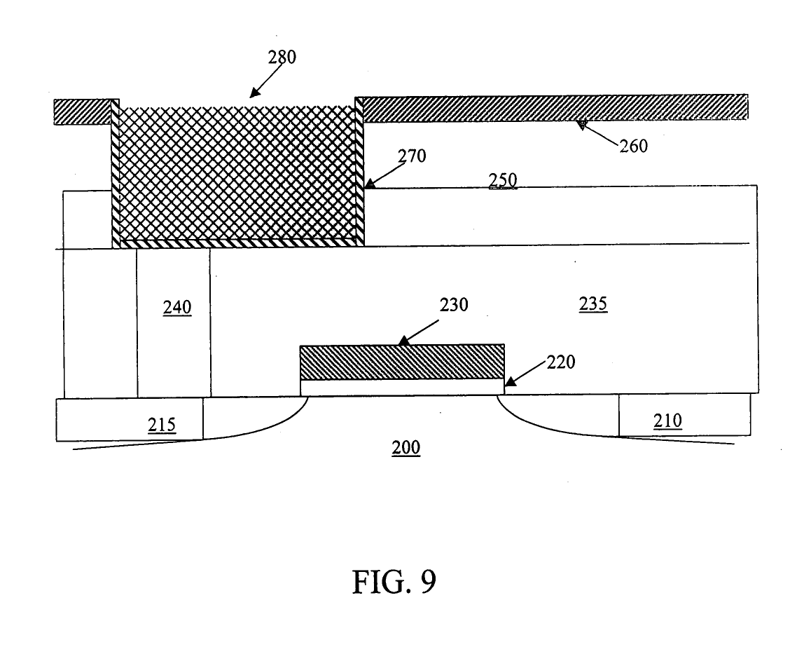

FIG. 9 shows the semiconductor device of FIG. 8 after it has been planarized by a planarization process using the method and apparatus of the present invention. The conductive material 280 has been planarized and removed from the surface of the pre-capping layer 260 so that the conductive material 280 only remains in the trench. The process planarizes and removes the conductive material 280 such that the conductive material 280 remains in the trench, leaving the conductive material relatively coplanar with the pre-capping layer. As shown on FIG. 9 the conductive material 280 is purposely slightly below the plane of the dielectric layer composed of the low dielectric constant material 250 in the pre-capping layer 260. This slight difference in heights is often referred to in the industry as “dishing.” Here, dishing is controlled such that the step height is not greater than 1000 Angstroms, as described above. Typically, the average step height of multiple features is not greater than about 500 Angstroms. The structure in FIG. 9 is called a Damascene structure or inlaid structure. Alternatively, the via and trench may be simultaneously filled with conductive material such as copper and then planarized to form a dual Damascene or dual inlaid structure as is known in the industry.

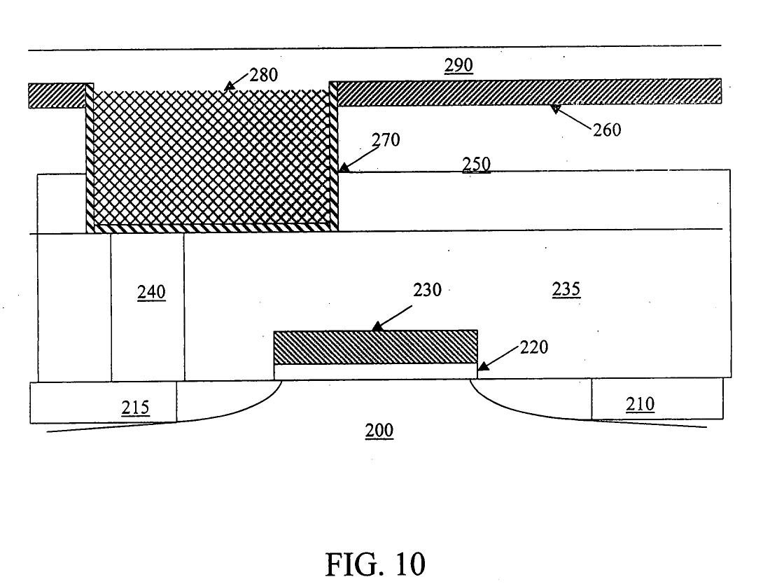

In FIG. 10 a post-capping layer 290 is deposited over the surface covering the conductive material 280 and the pre-capping layer 260. The post-capping layer 290 also covers the surface of material with low dielectric constant 250 that may have been exposed by the planarization process, and generally overlies the layer 250.

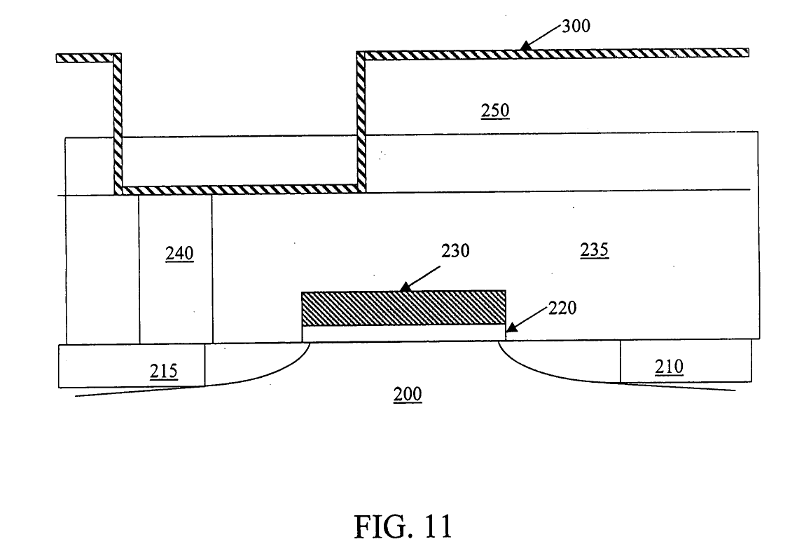

FIG. 11 depicts the semiconductor device of FIG. 4 which has undergone an alternative process in which the step of depositing a pre-capping layer 260 of FIG. 5 has been skipped so that the etching of a trench and deposition of the barrier layer 300 were carried out directly on the low dielectric constant material 250.

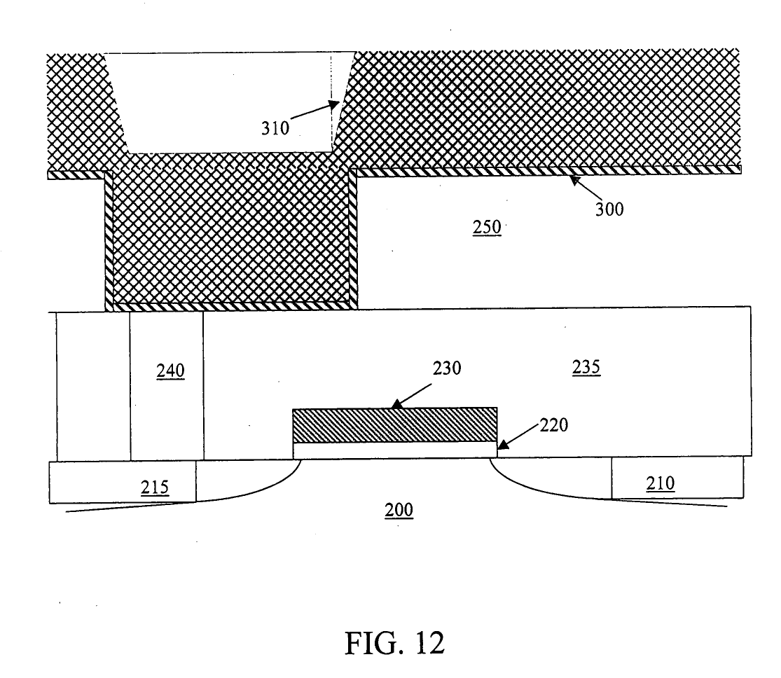

FIG. 12 shows the device of FIG. 11 on which a layer of conductive material 310 has been deposited over the barrier layer 300 using an embodiment of the method and apparatus of the present invention. The conductive material 310 is deposited to completely fill the trench.

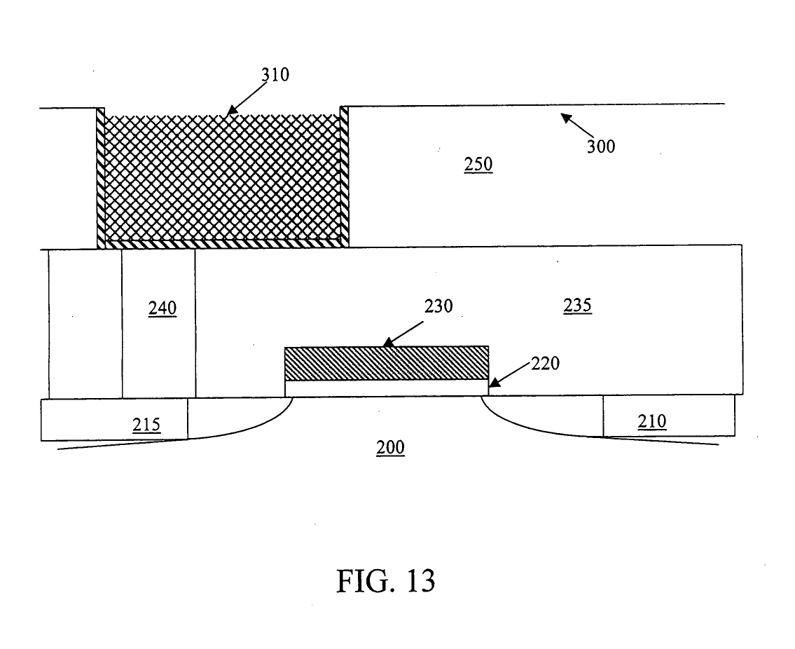

FIG. 13 shows the semiconductor device of FIG. 12 after it has been planarized by a planarization process using an embodiment of the method and apparatus of the present invention. The conductive material 310 of FIG. 12 has been planarized and removed from the surface of the dielectric material 250. The process planarizes and removes the conductive material 310 such that the conductive material 310 remains in the trench, leaving the conductive material 310 relatively coplanar with the dielectric material 250.

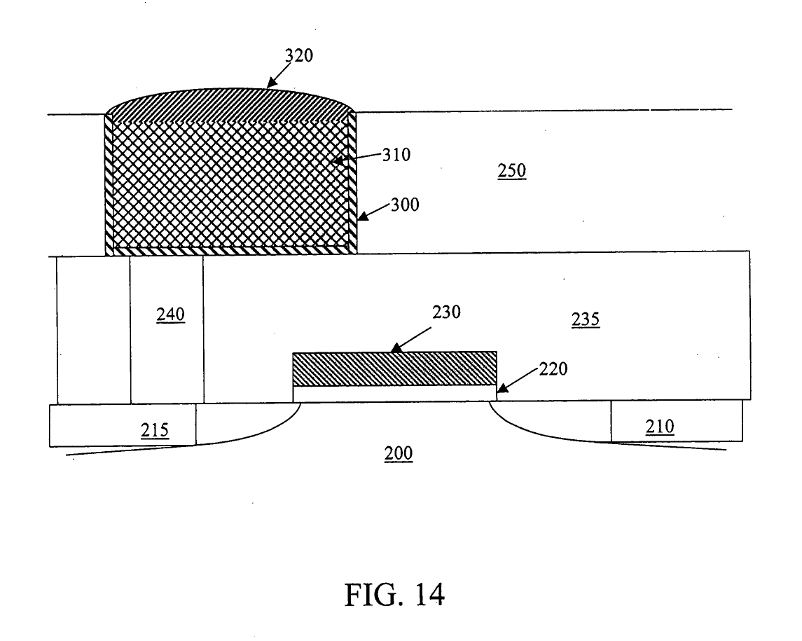

FIG. 14 shows the device in FIG. 13 after a selective capping layer 320 has been deposited to cover the conductive material. The deposition may be done by electroless plating.

In another embodiment, the method and apparatus of the present invention may be used to simultaneously deposit and remove a conductive material such as copper. In this embodiment, the simultaneous deposition fills the via and/or trench with the conductive material and the simultaneous removal planarizes the surface of the conductive material. In yet another embodiment, the conductive material may be deposited in the same chamber prior to the removal and planarizing.

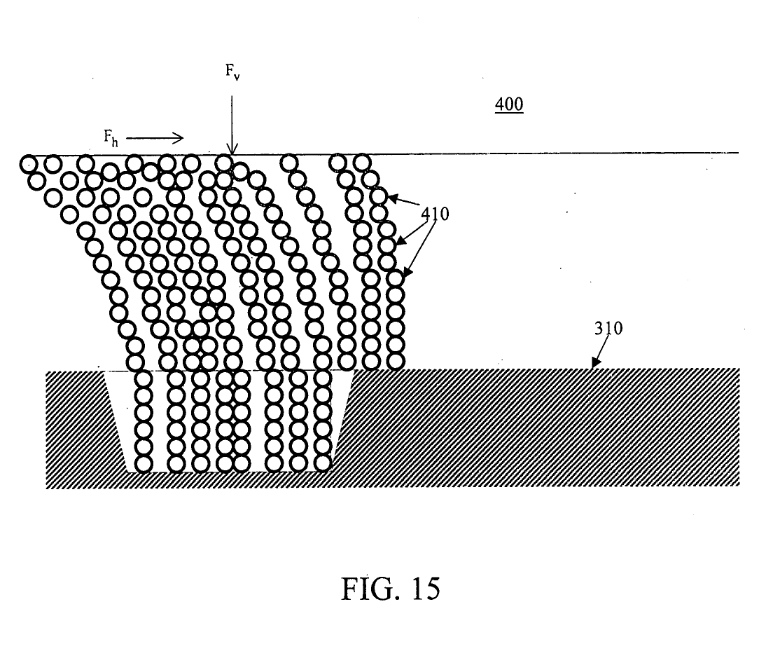

FIG. 15 depicts a prior art approach for polishing in which a polishing pad 400 is pressed against particles 410 that are between the pad 400 and the surface 310, and are aligned in a magnetic field. In this approach, the pad 400 is pressed down against the particles with a force, Fᵥ, and moved laterally with respect to the wafer surface 310 with a horizontal force, Fₕ. Here, the particles are contacted and pressed towards the surface 310 by a global force, the pad forcing the interconnected and contacting groups of particles against the surface to be polished. Individual particles are not biased with a force generated by a field to translate the particles towards the surface 310, and as such, efficacy of polishing is sacrificed.

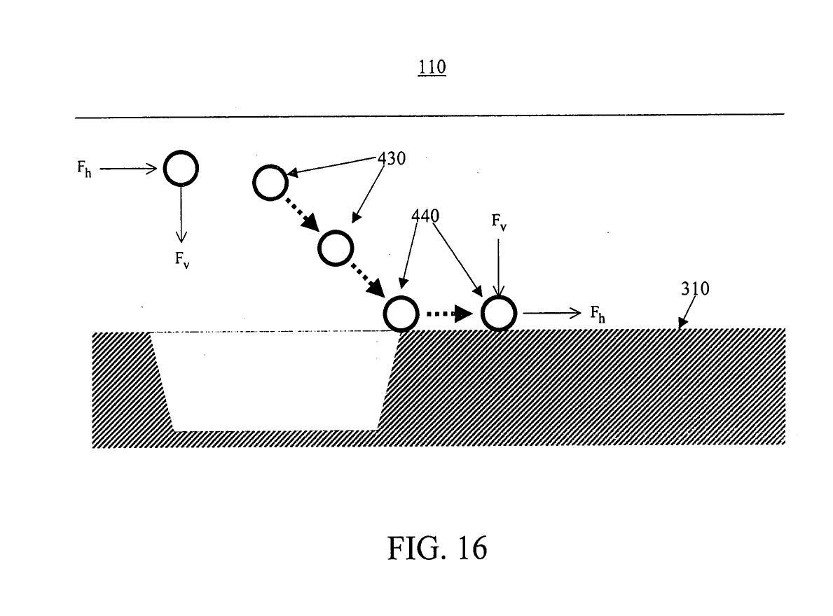

FIG. 16 shows an approach for planarization using an embodiment of the present invention. In this case, the particles 430 are in a generated field that bias the individual particles 430 towards the surface of the wafer with a vertical force, Fᵥ. There is also a horizontal force, Fₕ, on particles in this embodiment created by the flow of fluid between an upper lid 110 and the surface of the wafer 310. The horizontal force, Fₕ, on the particles may also be created by other means such as a pad contacting the particles. The horizontal and vertical forces cause particles 430 that are above the surface of the wafer to move towards the surface of the wafer, and particles that are at the surface of the wafer 440 to move along the surface of the wafer while pressing against the surface of the wafer with force Fᵥ, enabling removal of material at the surface.

According to embodiments of the present invention, several advantages may be provided. For example damage to the wafer surface is attenuated. In conventional CMP processing, scratching can occur due to particles embedded in the CMP pad, which are dragged across the surface of the wafer. Such an approach of pressing particles against the surface with a polishing pad can cause significant surface scratching, while use of individually biased particles according to embodiments herein eliminates a polishing pad that can cause embedded particles to initiate surface damage to the material of the polished wafer (e.g., soft low k materials or metal lines). Further, excellent surface topography, in particular, planarity, is achieved, particularly in the context of hard-to-planarize metal/low k materials.

According to certain embodiments, processing costs may be reduced by provision of a lower cost tool, and reduction in consumable costs such slurry and polishing pads.

While embodiments have disclosed herein with particularity, it is understood that modification may be made thereto, such as by one of ordinary skill in the art, and still fall within the scope of the claims herein.

1. A method for planarizing a semiconductor wafer, comprising:
providing a fluid on a surface of the wafer, the fluid containing particles; and
generating a field to apply a force to the particles, the force having a component that is normal to the surface such that the particles contact the surface to remove material therefrom.

2. The method of claim 1, wherein the force from the field is effective to translate the particles to the surface of the wafer.

3. The method of claim 1, wherein the force is applied without use of a polishing pad.

4. The method of claim 1, wherein the force is applied absent direct contact with the particles.

5. The method of claim 1, wherein the fluid comprises a liquid.

6. The method of claim 1, further comprising applying another force to the particles, having a component that is parallel to the surface of the wafer.

7. The method of claim 5, wherein the fluid contains a chemical additive selected from the group consisting of oxidizing agents and complexing agents.

8-18. (canceled)

19. The method of claim 1, wherein the material removed from the surface comprises copper.

20. (canceled)

21. The method of claim 19, wherein the conductive material overlies a dielectric layer, and the conductive material is removed to expose the dielectric layer, wherein the dielectric layer comprises a dielectric material having a dielectric constant less than about 3.

22-24. (canceled)

25. The method of claim 1, further comprising a step of depositing a layer on the semiconductor wafer.

26-28. (canceled)

29. The method of claim 25, wherein the layer is deposited by electroplating.

30. The method of claim 25, wherein the layer is deposited by electroless plating.

31. (canceled)

32. The method of claim 25, wherein the steps of providing and generating are continued until an underlying material is exposed.

33. The method of claim 25, wherein the layer comprises a material selected from the group consisting of copper, silver, ruthenium, palladium, platinum, cobalt, nickel, tin, tungsten, phosphorus, boron, tantalum, titanium and nitrogen, and combinations thereof.

34-35. (canceled)

36. The method of claim 1, wherein the field is an energy field, comprising an electric field, a magnetic field, or a mechanical energy field.

37. The method of claim 36, wherein the field is a mechanical energy field, having mechanical waves that translate through the fluid.

38. The method of claim 1, further comprising a step of generating a field to bias the particles to translate away from the surface.

39.-40. (canceled)

41. A method of forming a semiconductor device, comprising:
depositing a dielectric layer on a semiconductor wafer;
depositing a conductive layer on the semiconductor wafer such that the conductive layer overlies the dielectric layer and defines an upper surface;
providing a fluid on the upper surface of the semiconductor wafer, the fluid containing particles; and
generating a field to force the particles in the fluid to impact the upper surface of the semiconductor wafer and remove material therefrom.

42. The method of claim 41, further comprising a step of forming an active device, over which the dielectric layer is deposited.

43. The method of claim 41, further comprising a step of forming an opening in the dielectric layer, such that the conductive layer extends into the opening.

44-64. (canceled)
